(19) United States
(12) Patent Application Publication
(10) Pub. No.: US 2025/0298097 A1
(43) Pub. Date: Sep. 25, 2025

(54) GMR LAYOUT FOR COMPACT TRANSDUCER WITH MISMATCH CONTROL

(71) Applicant: Allegro MicroSystems, LLC, Manchester, NH (US)

(72) Inventors: Rémy Lassalle-Balier, Bures sur Yvette (FR); Alexander Latham, Harvard, MA (US); Guillermo Airaldi, Salinas Canelones (UY)

(73) Assignee: Allegro MicroSystems, LLC, Manchester, NH (US)

(21) Appl. No.: 18/609,375

(22) Filed: Mar. 19, 2024

(51) Int. Cl. G01R 33/09; H10N 50/10; H10N 59/00

(52) U.S. Cl. CPC G01R 33/09; H10N 50/10; H10N 59/00

(57) ABSTRACT

A magnetoresistance (MR) structure includes one or more MR elements each having a serpentine layout formed from two or more groups of parallel lines, the two or more groups of parallel lines connected by a first plurality of metal pads at a first end of the MR structure and a second plurality of metal pads at a second end of the MR structure opposite from the first end. A coil structure and technique for exciting the one or more magnetoresistance (MR) elements are also disclosed.

### BACKGROUND

Magnetic field sensors utilize magnetic field sensing elements to detect one or more magnetic fields for various purposes. For example, magnetic field sensors are often used to detect a current flowing in a conductor. Magnetic field sensors may also be used to detect a ferromagnetic or conductive target and may generally act to detect motion or position of the target. Such sensors are found in many technology areas including robotics, automotive, manufacturing, biotechnology, and so forth.

Magnetoresistance (MR) elements are a class of magnetic sensing elements having a variable resistance that changes in response to changes in an applied or sensed magnetic field. There are different types of magnetoresistance elements, for example, semiconductor magnetoresistance elements such as ones including Indium Antimonide (InSb), anisotropic magnetoresistance (AMR) elements, giant magnetoresistance (GMR) elements, and tunneling magnetoresistance (TMR) elements, which are also referred to as magnetic tunnel junction (MTJ) elements.

### SUMMARY

Described herein are concepts, techniques, and structures for providing magnetoresistance elements (e.g., GMR elements) having a serpentine layout of narrow, parallel lines to achieve more compact transducers (in terms of space on the die), improved mismatch, and lower noise compared to the state of the art. Disclosed MR structures and layouts can be used in a variety of magnetic sensing applications, including but not limited to speed sensing, movement sensing, and near-field sensing such as magnetic biosensing.

Near-field sensing may rely on narrow stripes of MR with straight smooth edges and a repeatable pattern. Such applications may require MR elements to have a base resistance in the kilo Ohm range and a relatively large area of stripes. In contrast to MR elements having conventional yoke designs, disclosed MR structures are well-suited for such near-field sensing applications.

Also described herein are concepts, techniques, and structures for providing of excitation coils for use with such MR elements, and for arranging disclosed MR structures and coils into a matrix of pixels that can be individually read out for various applications including but not limited to biosensing or other near-field sensing applications.

According to one aspect of the disclosure, a magnetoresistance (MR) structure includes: one or more MR elements each having a serpentine layout formed from two or more groups of parallel lines, the two or more groups of parallel lines connected by a first plurality of metal pads at a first end of the MR structure and a second plurality of metal pads at a second end of the MR structure opposite from the first end.

In some embodiments, each of the two or more groups of parallel lines include at least two parallel lines. In some embodiments, each of the two or more groups of parallel lines include at least four parallel lines. In some embodiments, the two or more groups of parallel lines include at least eight groups of parallel lines, the first plurality of metal pads includes at least five metal pads, and the second plurality of metal pads includes at least four metal pads. In some embodiments, the first plurality of metal pads includes a first metal pad corresponding to a first terminal of the MR element and a second metal pad corresponding to a second terminal of the MR element. In some embodiments, the two or more groups of parallel lines are connected to allow current to flow between the first and second terminals of the MR element. In some embodiments, the two or more groups of parallel lines each include parallel lines of equal width. In some embodiments, each of the parallel lines of the same width include at least two parallel lines with adjacent pairs of the two parallel lines separated by equal spacing.

In some embodiments, the structure can include a first plurality of unconnected lines provided on a first side of the one or more MR elements and a second plurality of unconnected lines provided on a second side of the one or more MR elements opposite from the first side, the first and second pluralities of unconnected lines being electrically isolated from the one or more MR elements. In some embodiments, the first and second pluralities of unconnected lines both comprise at least two unconnected lines.

In some embodiments, the one or more MR elements includes at least two MR elements, wherein the serpentine layouts of the at least two MR elements are interleaved. In some embodiments, a first one of the at least two MR elements has a longer active area compared to a second one of the at least two MR elements. In some embodiments, the at least two MR elements are connected to form a half bridge. In some embodiments, the one or more MR elements includes four MR elements, wherein the serpentine layouts the four MR elements are interleaved. In some embodiments, the four MR elements are connected to form a full bridge.

According to another aspect of the disclosure, a coil structure for exciting one or more magnetoresistance (MR) elements includes: a first plurality of parallel traces; a second plurality of parallel traces; a first plurality of return paths connecting first ends of the first plurality of parallel traces to first ends of the second plurality of parallel traces; and a second plurality of return paths connecting seconds ends of the first plurality of parallel traces to second ends of the second plurality of parallel traces. The first and second pluralities of parallel traces extend in a first direction and the first and second pluralities of returns paths extend in a second direction perpendicular to the first direction.

In some embodiments, the first and second pluralities of parallel traces are formed on one or more metal layers and the first and second pluralities of return paths are formed on at least two other metal layers. In some embodiments, a first MR element is disposed over the first plurality of parallel traces, and a second MR element is disposed over the second plurality of parallel traces. In some embodiments, the first MR element comprises a first plurality of parallel lines, and the second MR element comprises a second plurality of parallel lines. In some embodiments, the first plurality of parallel lines are aligned with the first plurality of parallel traces, and the second plurality of parallel lines are aligned with the second plurality of parallel traces.

In some embodiments, ones of the first plurality of parallel traces are centered along respective ones of the first plurality of parallel lines, and ones of the second plurality of parallel traces are centered along respective ones of the second plurality of parallel lines. In some embodiments, the first plurality of parallel lines are separated by a first plurality of spaces, the second plurality of parallel lines are separated by a second plurality of spaces, the first plurality of parallel traces are centered along respective ones of the first plurality of spaces, and the second plurality of parallel traces are centered along respective ones of the second plurality of spaces.

According to another aspect of the disclosure, a method is provided for reading a sensor matrix, the matrix having pixels arranged in rows and columns, each pixel corresponding to one or more magnetoresistance (MR) elements, and further having a plurality of excitation coils each arranged to excite one or more pixels. The method includes: at a first time, passing current through a first one of the excitation coils to excite a first plurality of the pixels and obtaining first magnetic field measurements from the corresponding MR elements; and at a second time, passing current through a second one of the excitation coils to excite a second plurality of the pixels and obtaining second magnetic field measurements from the corresponding MR elements.

In some embodiments, exciting the first plurality of the pixels comprises exciting all pixels in a first row, and exciting the second plurality of the pixels comprises exciting all pixels in a second row. In some embodiments, exciting the first plurality of the pixels comprises exciting adjacent pixels in a first row and exciting adjacent pixels in a second row. In some embodiments, the first and second rows are offset by one, two, four, or six rows.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is a block diagram showing a back-biased magnetic field sensor having eight magnetoresistance (MR) elements, according to some embodiments of the present disclosure.

FIG. 2 is a schematic diagram showing how MR elements can be coupled in bridge arrangements to generate magnetic field signals, according to some embodiments.

FIG. 3 is a cross-sectional diagram of an illustrative magnetic-field biosensor using MR elements, according to some embodiments.

FIG. 4 is a cross-sectional diagram of an illustrative GMR stack from which disclosed MR element layouts may be formed.

FIG. 4A shows the GMR stack of FIG. 4A etched to have a plurality of narrow, parallel lines.

FIG. 5 is a top view diagram of a single-element MR structure with a serpentine parallel layout, according to some embodiments.

FIG. 5A is closeup view of a portion of the MR structure of FIG. 5.

FIG. 5B is an exploded view of the MR structure of FIG. 5.

FIG. 6 is a top view diagram of a two-element MR structure with a serpentine parallel layout, according to some embodiments.

FIG. 6A is closeup view of a portion of the two-element MR structure of FIG. 6.

FIG. 7 is a top view diagram of a four-element MR structure with serpentine parallel layout, according to some embodiments.

FIG. 8 is top view diagram of an excitation coil laid out under two single-element MR structures with serpentine parallel layouts, according to some embodiments.

FIG. 9 is top view diagram of an excitation coil laid out under two two-element MR structures with serpentine parallel layouts, according to some embodiments.

FIG. 10 is top view diagram of an excitation coil laid out under two four-element MR structures with serpentine parallel layouts, according to some embodiments.

FIG. 10A is a closeup view of a portion of the structure of FIG. 10.

FIG. 11 illustrating different power on techniques for column-based multiplexing using a matrix arrangement of MR elements, according to some embodiments.

The drawings are not necessarily to scale, or inclusive of all elements of a system, emphasis instead generally being placed upon illustrating the concepts, structures, and techniques sought to be protected herein.

### DETAILED DESCRIPTION

As used herein, the term “magnetic field sensing element” is used to describe a variety of electronic elements that can sense a magnetic field. The magnetic field sensing element can be, but is not limited to, a Hall effect element, a magnetoresistance (MR) element, or a magnetotransistor. As is known, there are different types of Hall effect elements, for example, a planar Hall element, a vertical Hall element, and a Circular Vertical Hall (CVH) element. As is also known, there are different types of MR elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of sensitivity perpendicular to a substrate, while metal based or metallic MR elements (e.g., GMR, TMR, AMR) and vertical Hall elements tend to have axes of sensitivity parallel to a substrate.

As used herein, the term “magnetic field sensor” is used to describe an assembly that uses a magnetic field sensing element in combination with an electronic circuit, all disposed upon a common substrate, e.g., a semiconductor substrate. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

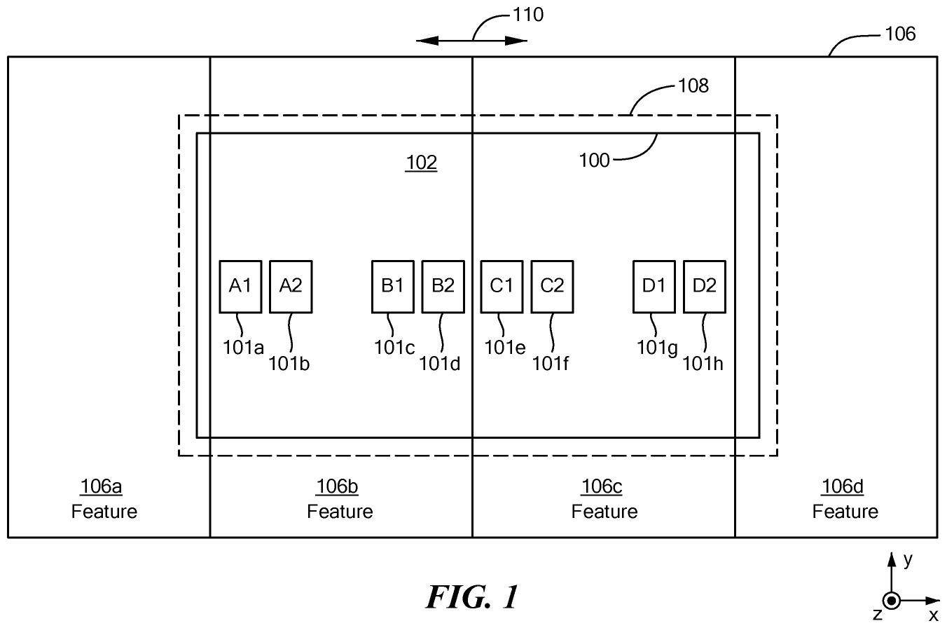

Referring to FIG. 1, a magnetic field sensor 100 can form a movement detector, operable to detect a movement of a ferromagnetic target object 106. The ferromagnetic target object 106 can be disposed over the magnetic field sensor 100, i.e., displaced in a direction parallel to a z-axis.

Magnetic field sensor 100 can include eight (8) MR elements 101a-h (also labeled A1, A2, B1, B2, C1, C2, D1, and D2) all disposed over a common substrate 102, for example, a semiconductor substrate. A largest surface of substrate 102 can be disposed in an x-y plane.

One or more of the MR elements 101a-h (e.g., all eight of the MR elements) may be provided having a serpentine layout of narrow, parallel lines to achieve more compact transducers (in terms of space on the die), improved mismatch, and lower noise compared to existing MR elements. In some cases, two or more of the 101a-h may be provided as a single structure that includes separate serpentine layouts for each MR element, with the separate serpentine layouts being interleaved (sometimes referred to as “interdigitated”). As used herein, the term “MR structure” refers to a semiconductor structure upon which one or more MR elements are formed or laid out. Examples of MR structures and layouts that may be used within magnetic field sensor 100 are shown in subsequent figures.

Ferromagnetic target 106 can include ferromagnetic features 106a-106d (e.g., alternating gear teeth and gear valleys of a gear). In some cases, target 106 may be formed from steel.

In a so-called “back-biased” arrangement” a magnet 108 can be coupled to or coupled within the magnetic field sensor 100 and disposed under the magnetic field sensor 100. For the back-biased arrangements, MR elements 101a-h are responsive to a magnetic field generated by the magnet 108, and more particularly, to changes in amplitude and angle of the magnetic field generated by the magnet 108 as the ferromagnetic target 106 moves. MR elements 101a-h can have respective maximum response axes parallel to the x-axis and can be responsive to a movement of the ferromagnetic target object 106 in one or two directions parallel to the x-axis as indicated by line 110.

Each of the MR elements 101a-h may have two terminals (e.g., metal contacts) connected to a voltage (e.g., a fixed reference voltage) to produce a current that varies in response to movement of ferromagnetic target 106. In other cases, a current can be applied to an MR element terminal to produce an output voltage responsive to the target 106. Multiple ones of the MR elements 101a-h can be connected together to form one or more half bridges or full bridges, with each half/full bridge providing a magnetic field signal. The magnetic field signal(s) can be provided as input to front-end circuitry configured to generate an output signal that conveys information about the target's movement, such as speed and direction of rotation. Such front-end circuitry can include amplifiers, filters, analog-to-digital converters (ADC), and digital signal processing (DSP), for example.

While FIG. 1 shows an example of a sensor with eight (8) MR elements, the general concepts and structures sought to be protected herein can be applied to sensors having other numbers of MR elements, such as one (1), two (2), three (3), four (4), or sixteen (16) elements.

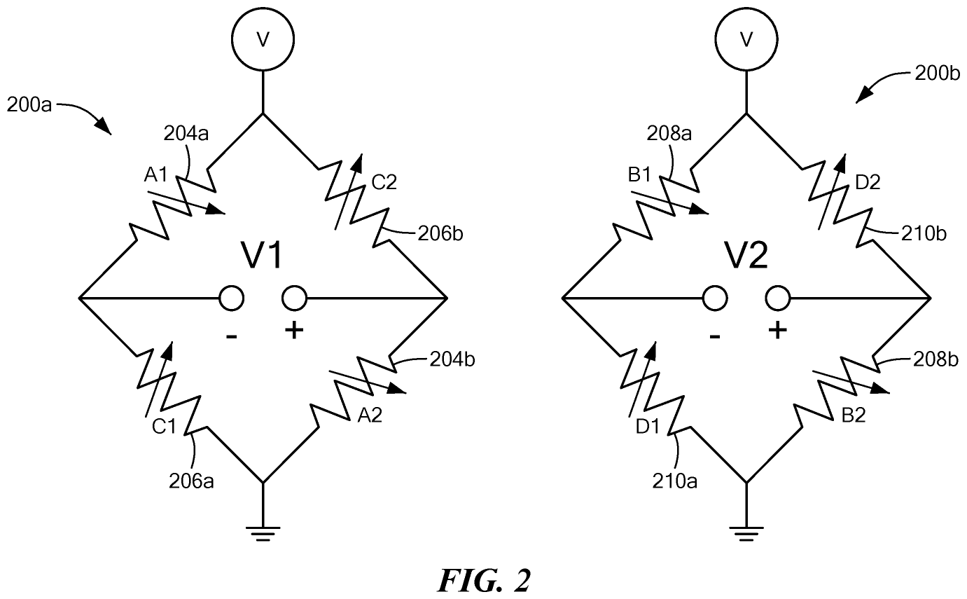

Turning to FIG. 2, eight MR elements A1, A2, B1, B2, C1, C2, D1, and D2 can be coupled in two bridge circuits to generate two differential signals, related to so-called “speed signals,” each having a respective cycle period indicative of a speed of motion of a target object, and each having a different phase, a sign of which is indicative of a direction of the motion. In more detail, a first bridge circuit 200a is comprised of MR elements A1, A2, C1, and C2 represented as variable resistors 204a, 204b, 206a, and 206b, respectively. A second bridge circuit 200b is comprised of MR elements B1, B2, D1, and D2 represented as variable resistors 208a, 208b, 210a, and 210b, respectively.

The MR elements A1, A2, B1, B2, C1, C2, D1, and D2 in FIG. 2 may be the same as or similar to MR elements 101a-h of FIG. 1, for example. As previously discussed, multiple MR elements can be formed as a single MR structure. Thus, for example, a bridge circuit may be formed from four (4) one-element MR structures, two (2) two-element MR structures, or from one (1) four-element MR structure. As another example, two bridge circuits (as in FIG. 2) can be formed from eight (8) one-element MR structures, four (2) two-element MR structures, or from one (2) four-element MR structures. A given bridge circuit may use MR elements formed on two or more different MR structures, with appropriate electrical connections made between said MR elements. Examples of one-, two-, and four-element MR structures are shown in subsequent figures.

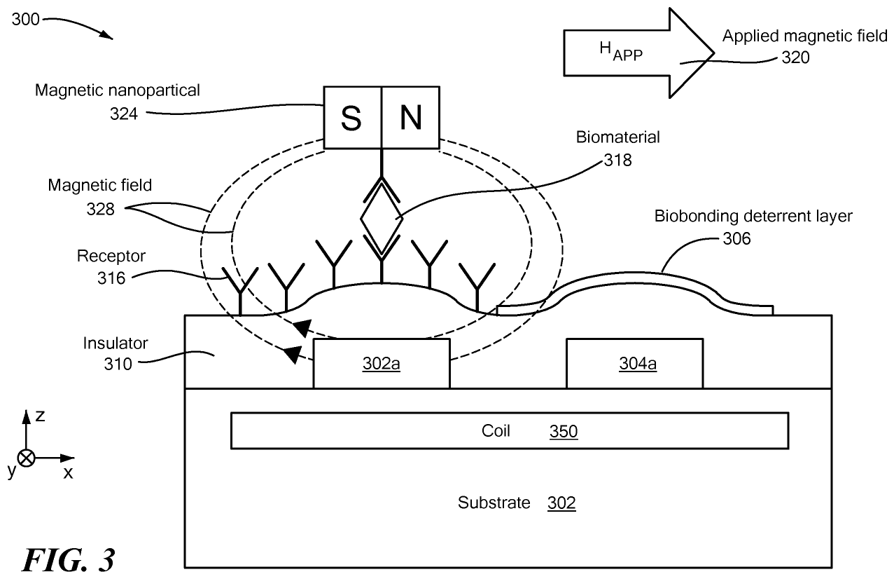

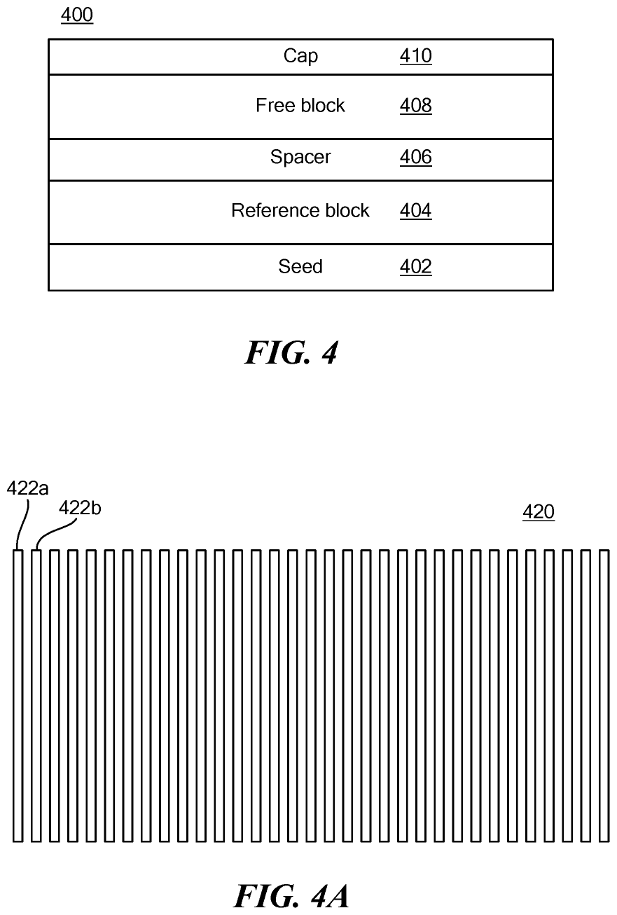

Referring to FIG. 3, a magnetic-field biosensor 300 includes the substrate 302 with two (2) MR elements 302a, 304a provided on a top surface of substrate 302. MR elements 302a, 304a can be encapsulated in an insulator 310 that prevents oxidation of the MR elements. One or more receptors 316 are attached to the top surface of the insulator 310 above MR element 302a. Receptors 316 can capture specific biological material, such as biomaterial 318. A biobonding deterrent layer 306 is disposed on the top surface of the insulator 310 above MR element 304a. Biobonding deterrent layer 306 can prevent any receptors from attaching thereto. In one example, biobonding deterrent layer 306 may include a layer of octadecyltrichlorosilane.

A fluid can be poured on the surface of insulator 310. Specific biomaterial present in the fluid can be captured by receptors 316. Sensor 300 can be later washed and a solution with one or more magnetic nanoparticles 324 (that are configured to attach to the biomaterial 318) can be poured on the sensor 300. If biomaterial 318 is attached to one or more receptors 316, then magnetic nanoparticles 324 are attached to each of the biomaterial and stay attached even after another wash of the magnetic biosensor 300.

In the configuration of FIG. 3, MR element 302a detects more of the magnetic field 328 from magnetic nanoparticles 324 than does MR element 304a. In one example, a detection of magnetic field 328 of magnetic nanoparticles 324 (and hence, the detection of the biomaterial 318) is performed by taking a difference of electrical changes of the MR element 302a and electrical changes of MR element 304a by placing MR elements 302a, 304a in a half bridge.

Magnetic nanoparticles 324 can generate a magnetic field 328. The magnetic nanoparticles 324 behave like a super paramagnet and can be collectively configured to align with an applied magnetic field 320. Otherwise, the magnetization directions of the magnetic nanoparticles are randomly distributed. MR elements 302a, 304a may be connected in series or in parallel to form a single device used to detect magnetic field 328 from magnetic nanoparticles 324 and thereby detect biomaterial 318. In this configuration, a magnetic field measured at the MR elements 302a, 304a may be opposite to applied magnetic field 320.

In some embodiments, magnetic field 320 can be generated in the x-z plane, with the field generated near the center of coil 350 being primarily in the direction of the z axis. Thus, the field applied to MR elements 302a, 304a may be primarily in the x-axis direction. The x, y, and z axes are labeled in FIG. 3.

In other examples, magnetic-field biosensor 300 in FIG. 3 may be expanded. In one example, the magnetic-field biosensor 200 may further include two more MR elements, one located under another biobonding deterrent layer and the other located under one or more additional receptors. The additional components may extend into the page of FIG. 3 or be side-by-side with the components in FIG. 3. The four (4) MR elements may be disposed in a full bridge. A differential output of the full bridge may be used to determine if magnetic nanoparticles exist.

In other examples, additional pairs of MR elements may be further expanded into the page of FIG. 3 and/or side-by-side with the components in FIG. 3 with one additional MR element in a pair located under a biobonding deterrent layer and the other located under one or more receptors. The MR elements may be disposed in a full bridge. A differential output of the full bridge may be used to detect if magnetic nanoparticles exist.

One or more MR elements used within magnetic biosensor 300 may be provided having a serpentine layout of narrow, parallel lines to achieve more compact transducers (in terms of space on the die), improved mismatch, and lower noise compared to existing MR elements. In some cases, two or more of the MR elements may be provided as a single structure that includes separate serpentine layouts for each MR element, with the separate serpentine layouts being interleaved. Examples of MR structures and layouts that may be used within magnetic biosensor 300 are shown in subsequent figures.

As shown in the example of FIG. 3, a magnetic biosensor can include one or more excitation coils 350 configured to generate applied magnetic field 320 when excited with an electric current. In some cases, excitation coils 350 may include two coils positioned under respective ones of the two MR elements 302a, 304a. In some cases, the two coils may have parallel lines that are aligned with parallel lines of the respective MR elements 302a, 304a. Examples of excitation coils structures and layouts that may be used within a magnetic biosensor are shown in subsequent figures.

FIG. 4 shows an example of a GMR stack 400 from which disclosed MR element layouts may be formed. The GMR stack 400 includes a seed layer 402, a reference block layer 404, a spacer layer 406, a free block layer 408 (or “free layer block”), and a cap layer 410. The dimensions of, materials used within, and fabrication of the various layers 402, 404, 406, 408, 410 may be selected according to known techniques for producing GMR elements.

Once the GMR stack is fabricated, parallel lines can be formed by removing material from all layers, by etching from the top of the cap layer 410 through to the bottom of seed layer 402. Several such etchings can be made at fixed distances apart, leaving a plurality of parallel lines 422a, 422b, etc., as illustrated by structure 420 of FIG. 4A. One or more metal pads (not shown) may be applied to a top layer of structure 420 to electrically connect parallel lines together and provide a serpentine layout of narrow, parallel lines, such as illustrated in subsequent figures. The structures illustrated in FIGS. 4 and 4A are not meant to be to scale.

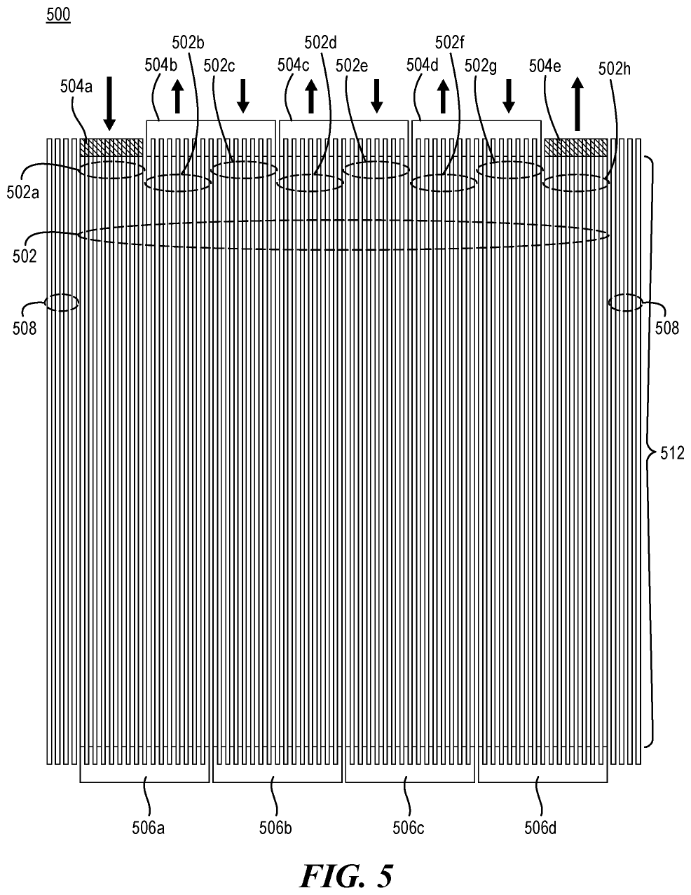

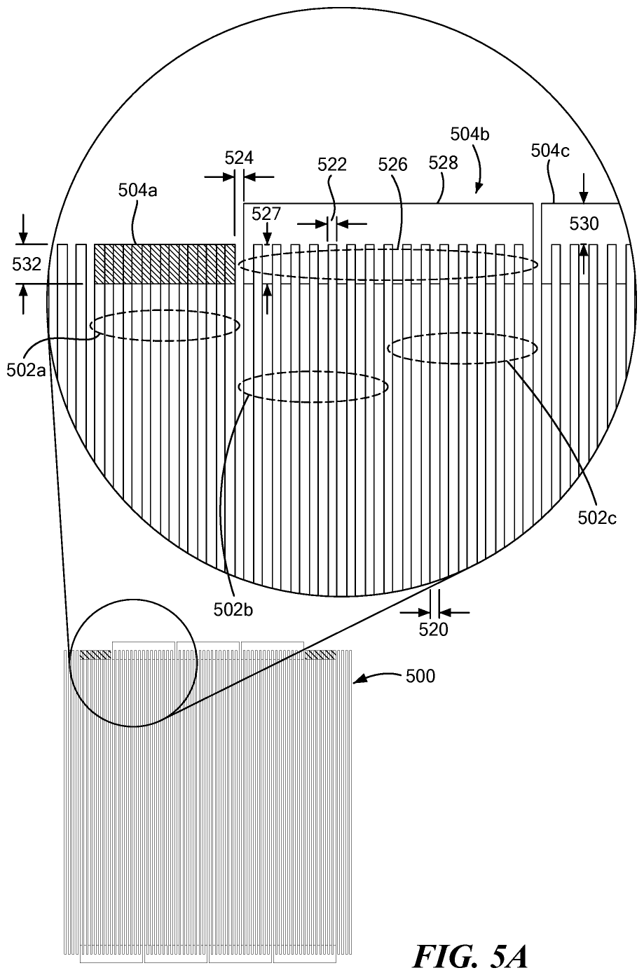

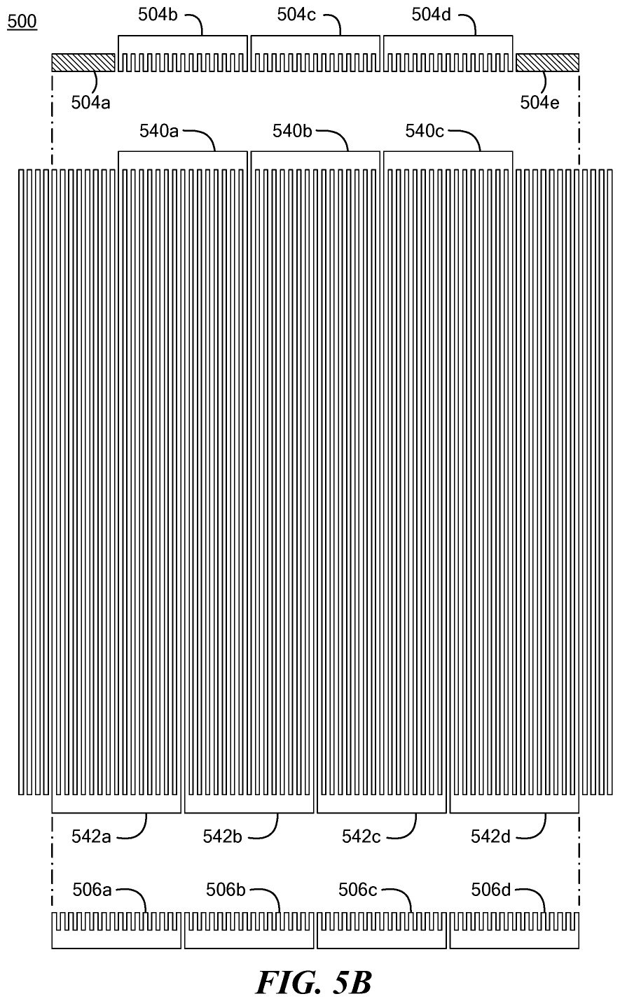

FIG. 5 shows an example of a single-element MR structure 500 having a serpentine layout of narrow, parallel lines, according to some embodiments. MR structure 500 can have an overall rectangular shape, but with protruding shorts for magnetic noise rejection (as more clearly seen in FIG. 5B). MR structure 500 includes a plurality of parallel lines 502, a first plurality of metal pads 504a-e (504 generally) arranged about a first end of the MR structure, and a second plurality of metal pads 506a-d (506 generally) arranged along an opposite end. The parallel lines 502 may be formed using an etching process, for example. The metal pads 504, 506 may be comb-shaped and deposited or otherwise formed onto the ends of parallel lines 502, as discussed further below.

Two of the metal pads may correspond to terminals of the MR element, whereas the other metal pads are provided to interconnect the parallel lines in a serpentine layout. In the example of FIG. 5, metal pads 504a and 504e correspond to the terminals, whereas metal pads 504b-d, 506a-d are provided to achieve a serpentine layout. The parallel lines 502 may be treated as being divided into M groups each having N adjacent parallel lines. In the example of FIG. 5, there are eight groups (M=8) 502a-h each having eight (N=8) adjacent parallel lines, for a total of sixty-four (64) parallel lines 502. Each group of parallel lines 502a-h can be connected to one of the first plurality of metal pads 504 and to one of second plurality of metal pads 506, with the terminal metal pads (e.g., pads 504a and 504e) both connected to a single group (e.g., groups 502a and 502h, respectively) and the non-terminal metal pads (e.g., metal pads 504b-d, 506a-d) each being connected to two adjacent groups of parallel lines. In this arrangement, current can flow between the two terminals 504a, 504e following a serpentine layout, as illustrated by alternating arrows in the figure.

In more detail, and as an example, current can flow between terminals 504a, 504e in the following manner:
across a first group of parallel lines 502a to metal pad 506a in a first direction (top-to-bottom of the page of FIG. 5);
across a second group of parallel lines 502b to metal pad 504b in a second opposite direction (bottom-to-top of the page of FIG. 5);
across a third group of parallel lines 502c to metal pad 506b in the first direction;
across a fourth group of parallel lines 502d to metal pad 504c in the second direction;
across a fifth group of parallel lines 502e to metal pad 506c in the first direction;
across a sixth group of parallel lines 502f to metal pad 504d in the second direction;
across a seventh group of parallel lines 502g to metal pad 506d in the first direction; and
across an eight group of parallel lines 502h to terminal 504e in the second direction.

The particular number of groups and number of parallel lines per group shown in FIG. 5 is merely illustrative, and other numbers may be used (adjusting the number of metal pads 504, 506 as needed). In some cases, the values of M and N may be selected for tuning the active area while keeping the resistance in a sought range.

To ensure uniformity, it is desirable to have consistent line widths and spacings within each group of parallel lines and, in some cases, across the entire MR structure 500. To promote such consistency, one or more unconnected parallel lines (or “dummy lines”) 508 may be etched on outer edges of the MR structure 500, i.e., on either side of parallel lines 502 as shown. In the example of FIG. 5, four (4) unconnected lines 508 are provided along each of the outer edges. As used herein, an “unconnected” line refers to a line formed in an MR structure (e.g., a GMR stack) that is electrically isolated from any MR element formed on the MR structure.

The general layout illustrated in FIG. 5 and subsequent figures may be referred to as a “serpentine layout of parallel lines” or “serpentine parallel layout” for short. This disclosed layout can provide for a relatively large active area 512 with increased control of transducer impedance mismatch, while maximizing the sensitivity and minimizing the transducer footprint on the die. Moreover, because current flows over multiple parallel lines, disclosed MR elements and structures have tunable resistance (e.g., in range of a few kilohms).

FIG. 5A is closeup view of a portion of the MR structure 500 of FIG. 5, with like elements show using like reference designators. As shown, the parallel lines of the MR structure can have a width 520 and, within a given group, adjacent lines can be spaced apart by a distance 522. Adjacent groups (e.g., groups 502a and 502b) may be spaced part by a distance 524, which in some cases may be the same as the inter-group spacing distance 522.

One or more of the metal pads 504 may have a comb-shaped design, with each tooth of the comb connected to an individual one of the parallel lines, and with the teeth being interconnected by a shaft that extends perpendicular to the teeth. For example, metal pad 504b can have sixteen teeth 526 interconnected by a shaft 528, with eight teeth connected to different ones of the second group of parallel lines 502b and the other eight teeth connected to different ones of the third group of parallel lines 502c. The teeth may have a length 527 and a width substantially equal to the width 520 of the connected parallel lines. The shaft 528 of the comb design may have a length 530, as shown. Comb-shaped metal pads can be used to short magnetic noise coming from the intersection of the ends of parallel lines and the shaft portions of the metal pads (e.g., to short the ends of parallel lines 502b, 502c with shaft 528).

As shown, the metal pads that correspond to the terminals (e.g., metal pads 504a, 504e) may have a rectangular shape rather than a comb shape. The rectangular-shaped pads 504a, 504e can have a length 532, as shown. In some embodiments, the rectangular-shaped metal pads 504a, 504e may be replaced by comb-shaped pads (i.e., all metal pads may be comb-shaped). In some embodiments, the comb-shaped metal pads 504b-d may be replaced by rectangular-shaped pads (i.e., all metal pads may be rectangular shaped).

In some embodiments, width 520 may be in the range of 0.1 to 20 μm. In some embodiments, distance 522 may be in the range of 0.1 to 20 μm. In some embodiments, distance 524 may be in the range of 0.1 to 20 μm. In some embodiments, length 530 may be in the range of 0.3 to 20 μm. In some embodiments, length 532 may be in the range of 0.3 to 20 μm. These are non-limiting examples.

FIG. 5B is an exploded view of the single-element MR structure 500 showing a plurality of shorts 540a-c protruding from one end of the structure and a plurality of shorts 542a-d protruding from the other end of the structure. Shorts 540a-c can substantially align with metal pads 504b-d, respectively, and shorts 542a-d can substantially align with metal pads 506a-d, respectively, as shown.

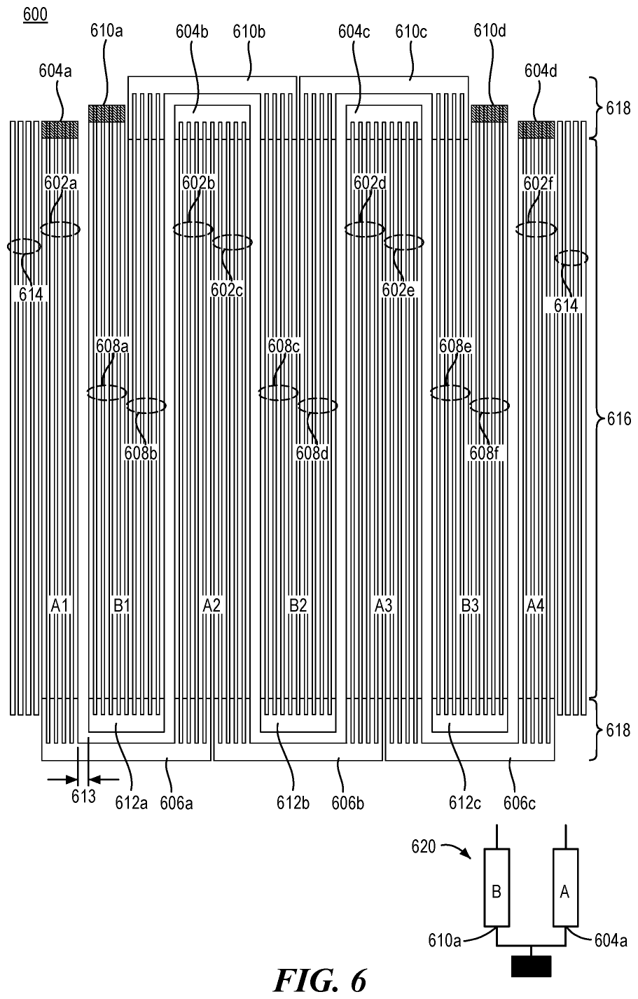

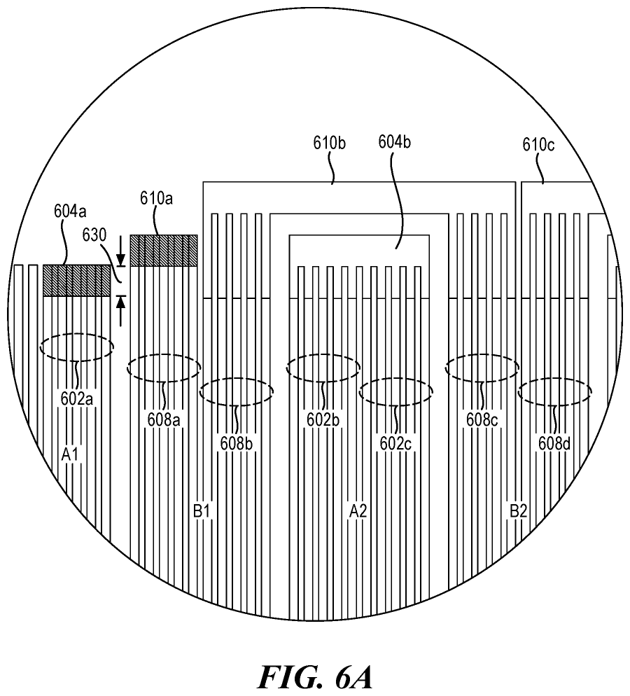

FIG. 6 shows an example of an MR structure 600 having two interdigitated MR elements with serpentine parallel layouts, according to some embodiments.

A first MR element is comprised of six (M=6) groups of four (N=5) parallel lines 602a-f (602 generally), a first plurality of metal pads 604a-d (604 generally) arranged about one end of the structure, and a second plurality of metal pads 606a-c (606 generally) arranged about an opposite end of the structure. Metal pads 604a, 604d correspond to the terminals of the first MR element. The groups of parallel lines 602 are alternatively connected between ones of the first and second pluralities of metal pads 604, 606 in a serpentine layout, as shown.

A second MR element is comprised of six (M=6) groups of five (N=5) parallel lines 608a-f (608 generally), a third plurality of metal pads 610a-d arranged about one end of the structure, and a fourth plurality of metal pads 612a-c arranged about an opposite end of the structure. Metal pads 610a, 610d correspond to the terminals of the second MR element. The groups of parallel lines 608 are alternatively connected between ones of the third and fourth pluralities of metal pads 610, 612 in a serpentine layout, as shown.

Other values of M and N may be used, with the number of metal pads 604, 606, 610, 612 being adjusted as appropriate.

One or more unconnected parallel lines 614 may be etched on outer edges of the MR structure 600, as shown. In the example of FIG. 6, four (4) unconnected lines 614 are provided along each of the outer edges.

The parallel lines 602, 608 may be formed using an etching process, for example. The metal pads 604, 606, 610, 612 may be comb-shaped and/or rectangular shaped, and deposited or otherwise formed onto the ends of the parallel lines 602, 608 similar to the metal pads described above in the context of FIGS. 5 and 5B. In the example of FIG. 6, metal pads 604a, 604d, 610a, and 610d corresponding to the terminals are rectangular-shaped, whereas the other metal pads 604b, 604c, 606a, 606b, 606c, 610b, and 610c are comb-shaped. In other embodiments, all metal pads may be either comb-shaped or rectangular-shaped.

The two MR elements provided by structure 600 are interdigitated. In more detail, the MR structure 600 can be viewed as having a plurality of interleaved “digits” each made up of one or more groups of parallel lines associated with a single MR element. In the example of FIG. 6, there are four digits A1-A4 associated with the first MR element (A) and three digits B1-B3 associated with the second MR element (B). The number of digits in the MR elements can vary based on the number of groups of parallel lines (M) used.

An interdigitated layout provides at least two geometric advantages. First, because of the first and second serpentine patterns of the two MR elements, a magnetic field experienced by these elements is necessarily averaged. Second, being interdigitated, the first and second MR elements have geometric centers that are close to each other, and thus, the MR elements experience nearly the same static magnetic fields across one or more axes. Therefore, the first and second MR elements have resistances, when coupled in half/full bridges, that have relatively little offset voltage in response to static magnetic fields.

In some applications, it may be necessary or desirable to space apart the parallel lines of one MR element from the other, to form a differential signal with engineered local field. For example, in FIG. 6, digits A1 and B2 can be spaced apart by a distance 613. The distance 613 can be, for example, twice the line spacing plus one line width (e.g., in the range of 0.9 to 60 μm). Likewise for digits B1 and A2, A2 and B2, etc. In some cases, this distance 613 can be equal to twice the line spacing plus one line width to ensure periodicity of the full structure. In some cases, these spaces may be filled with unconnected MR lines (not shown), similar to the unconnected lines 614 provided on the outer edges of the structure.

Otherwise, the width and spacing of parallel lines 602, 608 be similar to that of the parallel lines described above in the context of FIGS. 5 and 5A.

The two MR elements provided by structure 600 have an active area 616 not including the two metal contact areas 618 at opposing ends of the structure.

In some embodiments, the MR structure 600 can include protruding shorts along the top and bottom edges of the structure, similar to the protruding shorts described above in the context of FIGS. 5 and 5B.

FIG. 6 also illustrates how a half bridge 620 can be formed by connecting the first and second MR elements, here denoted A and B. One terminal from each of the two MR elements (e.g., terminals 604a and 610a) can be connected to form half bridge 620, as shown. The terminal connections shown are merely illustrative and other connections can be used.

The illustrative MR structure 600 can ensure the maximum efficiency in area allocation while providing the ability to create local fields that do not bleed over to the next element (e.g., when multiple elements are provided on a common die).

FIG. 6A is closeup view of a portion of the MR element of FIG. 6, with like elements shown using like reference designators. As shown, in some embodiments, a mismatch can be intentionally introduced between the two MR elements (A and B) to ensure that the remaining mismatch does not change polarity with process variability. To introduce such a mismatch, the outer lines (i.e., lines 608a and 608f) can be extended by a selected distance 630, as shown in the figure. Alternatively, one of the MR elements can be formed to have consistently longer lines (in terms of active area) than the other MR element. In any case, unbalancing half bridges can be used to avoid phase inversion of a demodulated output signal. In other embodiments, the MR structure may be designed so as to have substantially zero mismatch between the MR elements. For example, elements A and B can be designed to have the same active length with terminals at the same height.

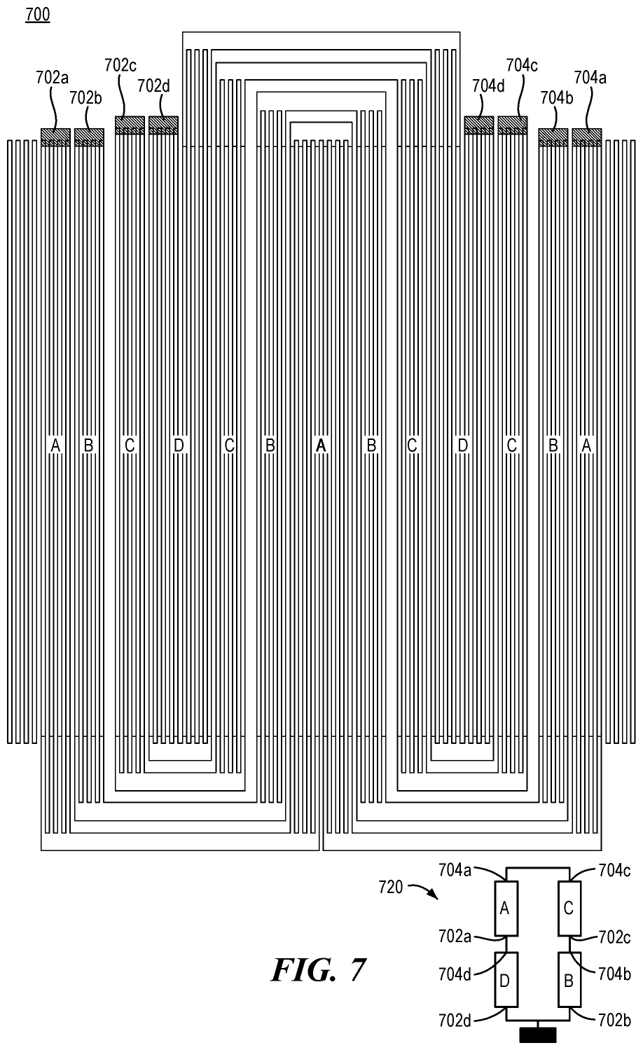

Turning to FIG. 7, the general concepts described above for FIGS. 5, 5A, 6, and 6A can be extended to provide an MR structure 700 having four elements, denoted A, B, C, and D. Each of the four MR elements comprises four (M=4) groups of four (N=4) parallel lines arranged in a serpentine layout and connected to a respective first terminal 702a-d and a respective second terminal 704a-d. The four MR elements can be interleaved as shown. Other values of M and N may be used.

As also shown in FIG. 7, a full bridge 720 can be formed by connecting the four MR elements, A, B, C, and D. The terminal connections shown are merely illustrative and other connections can be used.

Similar to the two-element MR structure of FIGS. 6 and 6A, mismatch can be intentionally introduced into a four-element structure by varying the line lengths of different MR elements, for example.

In contrast to the half bridge of FIGS. 6 and 6A, with the full bridge 720 of FIG. 7, it is not necessary to space apart the parallel lines of all MR elements from each other. In particular, lines for MR elements that are diagonally opposite in full bridge 720 (i.e., A and B, and C and D) can be kept tightly packed (e.g., within only one line spacing between them). The other pairs of MR elements (e.g., B and C) may be spaced apart as shown. In some cases, spacing can be equal to twice the line spacing plus one line width to ensure periodicity of the full structure. In some cases, these spaces may be filled with unconnected MR lines (not shown). Otherwise, the width and spacing of parallel lines in the embodiment of FIG. 7 be similar to that of the parallel lines described above in the context of FIGS. 5 and 5A.

In some embodiments, the MR structure 700 can include protruding shorts along the top and bottom edges of the structure, similar to the protruding shorts described above in the context of FIGS. 5 and 5B.

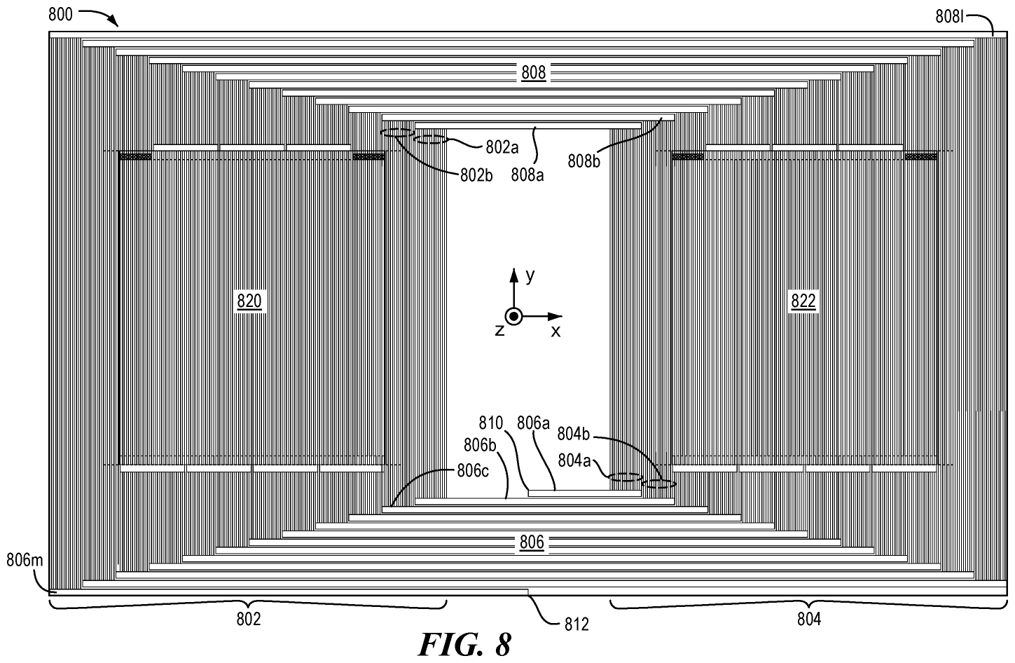

FIGS. 8-10 show examples of excitation coils laid out under MR structures with serpentine parallel layouts. This arrangement can be useful for near field applications where a local field source is required. For example, illustrated excitation coils may be used within magnetic-field biosensor of FIG. 3.

FIG. 8 shows an excitation coil structure 800 positioned under two single-element MR structures 820, 822 with serpentine parallel layouts, according to some embodiments. MR structures 820, 822 may be the same as or similar to the single-element MR structure of FIG. 5.

The coil structure 800 comprises a first plurality of narrow, parallel traces 802 (or “left traces”) and a second plurality of narrow, parallel traces 804 (or “right traces”). As shown, the left and right parallel traces 802, 804 can extend along a common axis (e.g., the y axis in FIG. 8).

The left and right traces 802, 804 are connected by a first plurality of conductive paths 806 (or “bottom return paths”) and second plurality of conductive paths 808 (or “top return paths”). In the example shown, there are thirteen (13) bottom return paths 806a, 806b, . . . , 806m and twelve (12) top return paths 808a, 808b, . . . , 8081. Other numbers of returns paths may be used, for example to increase or decrease the number of turns of the coil structure 800. The top and bottom return paths 806, 808 can extend along a common axis (e.g., the x axis in FIG. 8) that is perpendicular to that of traces 802, 804.

The innermost bottom return path 806a and the outermost bottom return path 806m provide terminals 810 and 812, respectively, of the coil. All other return paths 806, 808 are arranged to connect one or more left traces 802 to one or more right traces 804 in such a matter to allow current to flow between the terminals 810, 812 while spiraling through the coil structure 800 (e.g., in a counterclockwise direction) to produce a local field (e.g., in the direction of the z axis). For example, current entering terminal 810 can flow in the +x direction through a first bottom return path 806a, in the +y direction through a first group of right traces 804a, in the −x direction through a first top return path 808a, in the −y direction through a first group of left traces 802a to reach a second bottom return path 806b, completing a first turn of the coil. To complete a second turn, the current can flow in the +x direction through the second bottom return path 806b, in the +y direction through a second group of right traces 804b, in the −x direction through a second top return path 808b, in the −y direction through a second group of left traces 802b to reach a third bottom return path 806c. And so on, until the current reaches terminal 812 via the outermost bottom return path 806m.

It will be appreciated that illustrative coil structure 800 can maximize density by exciting two separate MR structures 820, 822.

In the example of FIG. 8, each turn of the coil includes eight (8) left traces 802 and eight (8) right traces 804. Other numbers of traces can be included in each term (e.g., depending on the MR element design).

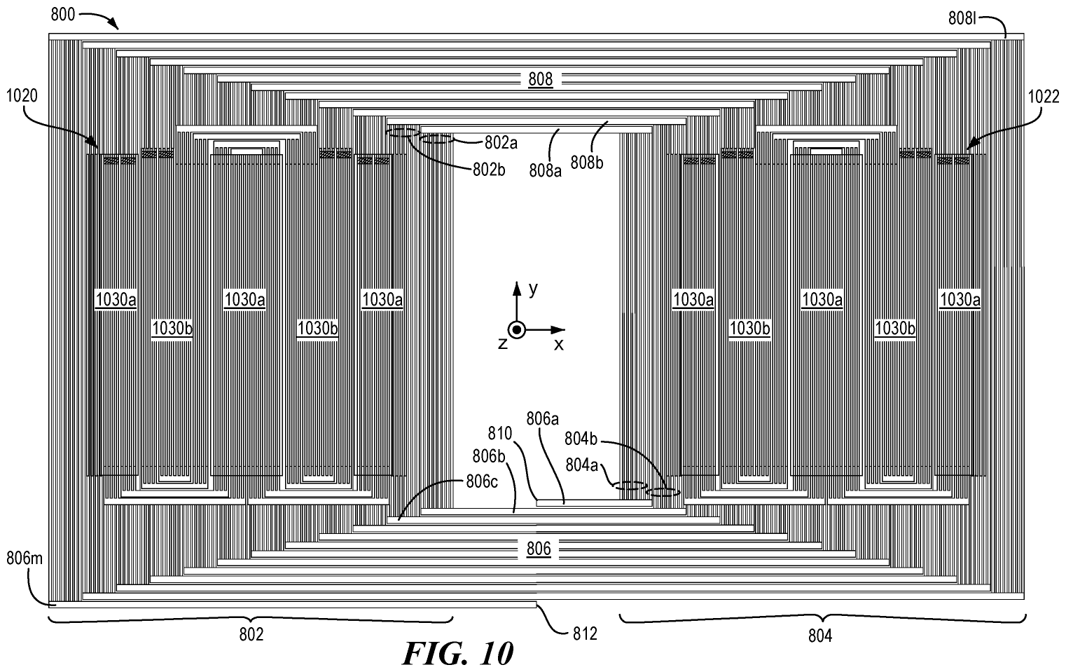

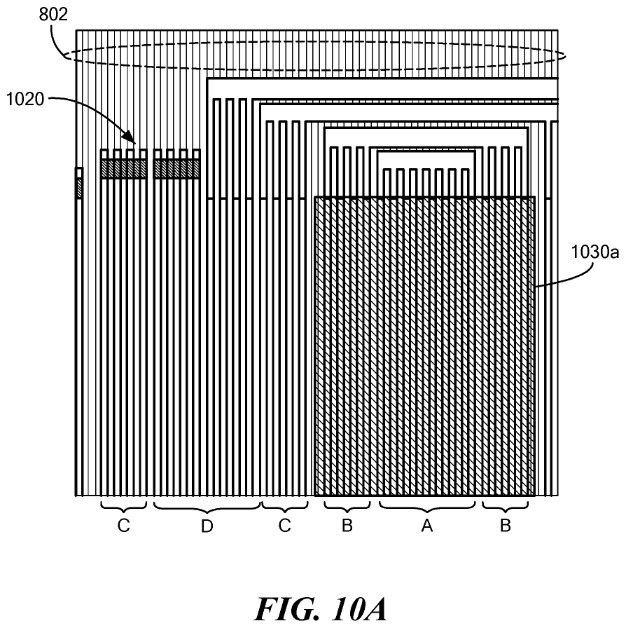

In some embodiments, the width and spacing of the left and right parallel traces 802, 804 may be selected to be substantially equal to that of the parallel lines making up the left and right MR structures 820, 822, respectively. In some cases, the parallel traces 802, 804 may be aligned with the parallel lines of the MR structures 820, 822, such as illustrated in FIG. 10A. Thus, each line of MR structure 820 may be aligned above a corresponding left trace 802, and each line of MR structure 822 may be aligned above a corresponding right trace 804. In other embodiments, a single trace of the excitation coil may be wide enough to span multiple MR element lines. To maximize the homogeneity of the field over MR lines, it may be preferable to either have one trace per MR line or many MR lines over a wide trace. In some cases, the coil traces may be wider or narrower than the MR parallel lines. In such cases, the coil traces may be centered along the MR parallel lines. In some cases, the coil traces may be centered along spacings between the MR parallel lines.

As shown in FIG. 8, the number of parallel traces 802, 804 can be larger than the number of parallel lines on MR structures 820, 822. In addition, the two MR structures 820, 822 may be off-center from each other (along the x axis) with respect to the coils, as shown. The number of extra traces and the MR element shift regarding traces center can be calculated or otherwise selected in order to have a homogeneous (±1%) created field on the MR element.

The traces 802, 804 and return paths 806, 808 can be formed from a conductive material, such as a metal. The traces 802, 804 can be laid out on a metal layer closest to the MR structures 820, 822 to reduce (and ideally minimize) the required power to generate the local field. For example, referring to FIG. 3, the traces of coil 350 may be formed on a metal layer positioned immediately below MR structures 302a, 304a, or close thereto. The return paths 806, 808 may be formed on one or more other metal layers below the coil layer and, preferably, on several other metal layers (e.g., at least two other metal layers) to reduce die area and coil resistance.

In an alternative embodiment, the return paths 806, 808 may be replaced by top and bottom parallel traces that run perpendicular to left and right traces 802, 804, resulting in a substantially square-shaped coil structure. The top and bottom parallel traces can be formed on the same topmost metal layer as left and right traces 802, 804. Additional MR structures can be positioned over the top and bottom parallel traces and rotated ninety degrees) (90° relative to left and right MR structures 820, 822.

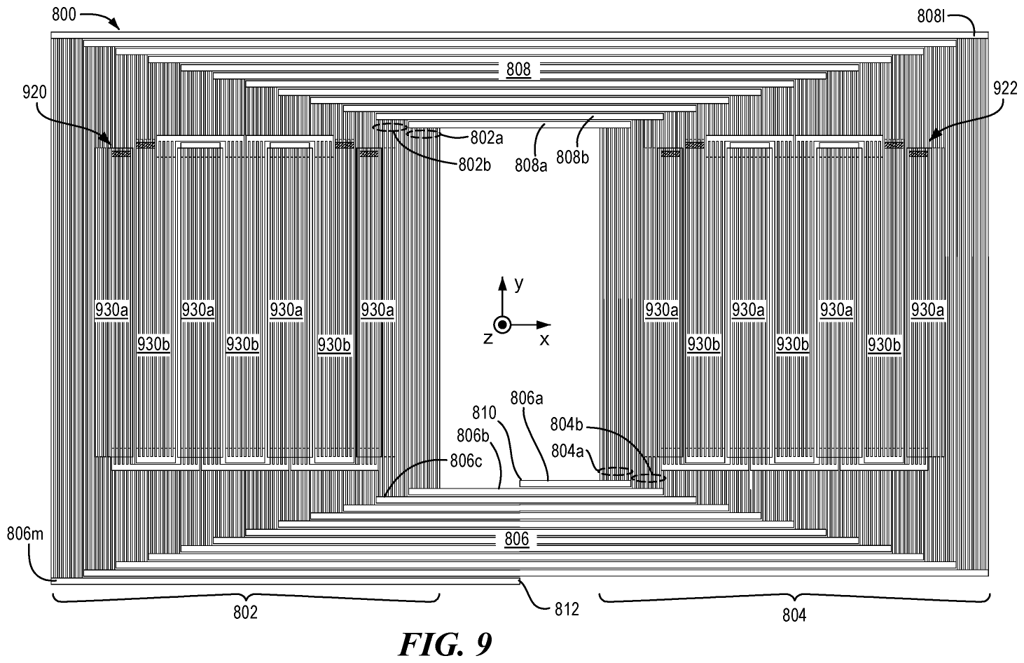

Turning to FIG. 9, in which like elements of FIG. 8 are shown using like reference designators, the excitation coil 800 can be laid out under two two-element MR structures 920, 922 with serpentine parallel layouts, according to some embodiments. MR structures 920, 922 may be the same as or similar to the two-element MR structure of FIG. 6.

In some applications (e.g., magnetic biosensing applications), the MR structures 920, 922 may be encapsulated in an insulator, such as illustrated by insulator 310 in FIG. 3. To space away the magnetic nanoparticle in the case of a magnetic immune assay, so that the half bridge or full bridge may sense a differential signal, the thickness of the insulator layer may vary across the MR structures. For example, as illustrated in FIG. 9, the insulator layer may be thinner above the regions 930a (corresponding to one MR element of the half bridge) compared to above the regions 930b (corresponding to the other MR element of the half bridge).

Turning to FIG. 10, in which like elements of FIG. 8 are shown using like reference designators, the excitation coil 800 can be laid out under two four-element MR structures 1020, 1022 with serpentine parallel layouts, according to some embodiments. MR structures 1020, 1022 may be the same as or similar to the four-element MR structure of FIG. 7.

MR structures 1020, 1022 may be encapsulated in an insulator, such as illustrated by insulator 310 in FIG. 3. The insulator layer may be thinner above the regions 1030a (corresponding to two MR elements of the full bridge) compared to above the regions 1030b (corresponding to the other two MR elements of the full bridge).

FIG. 10A is a closeup view of a portion of the structure of FIG. 10, with like elements shown using like reference designators. The portions of MR structure 1020 are labeled A, B, C, D to denote the four different MR elements. As can be seen, the MR element parallel lines are aligned with, and have the same width and spacing as, excitation coil traces 802.

The general excitation coil concepts and structures described above in the context of FIGS. 8-10 may provide one or more of the following benefits compared to the state of the art: (a) increased signal amplitude; (b) decreased crosstalk between neighboring transducers on the die; (c) decreased mismatch due to field inhomogeneity and temperature gradients; (d) decreased die footprint due to the coil while leaving access to as many metals as possible under the coil for the electronics; and (d) improved homogeneity of the field created by the coils on the MR lines while reducing the power consumption of the coil.

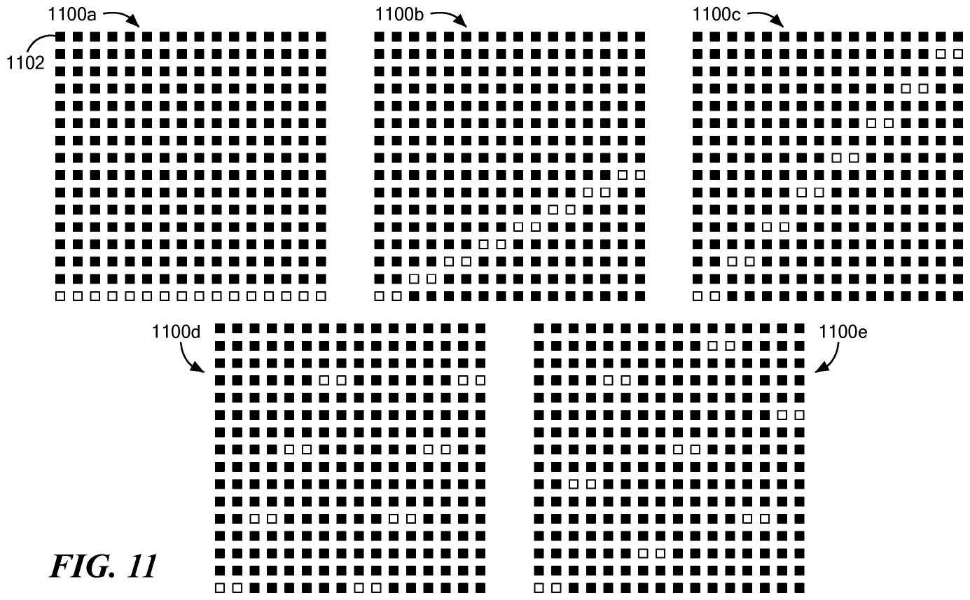

Referring to FIG. 11, a magnetic-field biosensor may be constructed using a matrix arrangement or MR elements.

Each pixel of the matrix (e.g., pixel 1102) may correspond to four MR elements. Thus, for example, each pixel may include (a) a single four-element MR structure such as shown in FIG. 7, (b) two two-element MR structures such as shown in FIG. 6, or (c) four single-element MR structures such as shown in FIG. 5. While FIG. 11 shows a 16×16 matrix, the general concepts and structures disclosed herein can be used to construct matrixes with other dimensions.

One or more excitation coils (not shown) may also be associated with each pixel. In some cases, adjacent pairs of pixels, both provided as four-element MR structures, may be excited using a common coil structure 800 as illustrated in FIG. 10. Thus, the number of excitation coils may be equal to half the number of pixels, in some examples.

Each pixel can be connected to front-end circuitry configured to obtain magnetic field measurements from the pixel's constituent MR elements, i.e. to “read” or “power on” pixel. Different circuit arrangements can be used. For example, each pixel can be connected to a separate front-end circuitry. As another example, different groups of pixels (e.g., different columns or rows in the matrix) can be connected to different front-end circuitry, with a multiplexer between each group of pixels and each front-end circuit to selectively read one or more of the group's pixels at a time. As another example, a single front circuit may be used along with a multiplexer to selectively read one or more pixels at a time. In some cases, frequency multiplexing can be used, in which case there is no need for a time multiplexer, but different excitation frequencies or bridge drive frequencies.

FIG. 11 shows five different multiplexing techniques that may be used in the case of separate front-end circuitry per column. In the figure, empty squares represent powered-on pixels and filled squares represent powered-off pixels.

With technique 1100a, all pixels in a given row are read together.

With techniques 1100b-e, pixels in adjacent columns are read together. This may be particularly useful in the case where a single excitation coil structure is used to excite two different MR structures (as in FIG. 10). After reading an adjacent pair of pixels, the row can be incremented, and the next pair of column-adjacent pixels can be read. With technique 1100b, adjacent pairs of pixels are initially offset by one (1) row. With techniques 1100c, 1100d, and 1100e, adjacent pairs of pixels are initially offset by two (2), four (4), and six (6) rows, respectively.

With all of the illustrated techniques 1100a-e, pixels may be incremented by one or more rows after each read, maintaining the initial offsets (if any). More specifically, a controller may select the next row as a function of the current row and a predetermined increment:

rowₙₑₓₜ=mod(row_{current}, increment)

, where increment is a value that be a hardwired or programmed value. In some cases, increment may be selected to ensure that the heat is scattered across the die both in time and space.

In some cases, a step size of six (6) may be preferred for a 16×16 because it provides maximum distance between powered on pairs of pixels. This means that the power dissipation is better distributed across the die, and it minimizes the cross talk between pixels. In general, the preferred step size may depend on the number of rows in the matrix.

In some cases, different pixels in the matrix can have different types of receptors to detect a different biomaterial. In one example, a magnetic-field biosensor may be constructed to detect many types of allergens or cancers at a time.

As used in the claims or elsewhere herein, the term “comprising” does not exclude other elements or steps, and the indefinite article “a” or “an” does not exclude a plurality.

As used herein, the term “predetermined,” when referring to a value or signal, is used to refer to a value or signal that is set, or fixed, in the factory at the time of manufacture, or by external means, e.g., programming, thereafter. As used herein, the term “determined,” when referring to a value or signal, is used to refer to a value or signal that is identified by a circuit during operation, after manufacture.

Various embodiments of the concepts systems and techniques are described herein with reference to the related drawings. Alternative embodiments can be devised without departing from the scope of the described concepts. It is noted that various connections and positional relationships (e.g., over, below, adjacent, etc.) are set forth between elements in the claims, detailed description, and drawings. These connections and/or positional relationships, unless specified otherwise, can be direct or indirect, and the claimed inventions are not intended to be limiting in this respect. Accordingly, a coupling/connection of entities can refer to either a direct or an indirect coupling/connection, and a positional relationship between entities can be a direct or indirect positional relationship. As an example of an indirect positional relationship, references in the present description to element or structure A coupled/connected to element or structure B include situations in which one or more intermediate elements or structures (e.g., element C) is provided between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

The terms “parallel” and “perpendicular” are used in various contexts herein. It should be understood that the terms parallel and perpendicular do not require exact perpendicularity or exact parallelism, but instead it is intended that normal manufacturing tolerances apply, which tolerances depend upon the context in which the terms are used. In some instances, the term “substantially” is used to modify the terms “parallel” or “perpendicular.” In general, use of the term “substantially” reflects angles that are beyond manufacturing tolerances, for example, within +/−ten degrees.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the detailed description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

Other variations to the disclosed embodiments can be understood and effected by those skilled in the art in practicing the claimed invention, from a study of the drawings, the disclosure, and the appended claims.

The mere fact that certain measures are recited in mutually different dependent claims does not indicate that a combination of these measures cannot be used to obtain an advantage.

Any reference signs in the claims should not be construed as limiting the scope.

All publications and references cited herein are expressly incorporated herein by reference in their entirety.

1. A magnetoresistance (MR) structure comprising:
one or more MR elements each having a serpentine layout formed from two or more groups of parallel lines, the two or more groups of parallel lines connected by a first plurality of metal pads at a first end of the MR structure and a second plurality of metal pads at a second end of the MR structure opposite from the first end.

2. The MR structure of claim 1 wherein each of the two or more groups of parallel lines include at least two parallel lines.

3. The MR structure of claim 2 wherein each of the two or more groups of parallel lines include at least four parallel lines.

4. The MR structure of claim 1 wherein the two or more groups of parallel lines include at least eight groups of parallel lines, the first plurality of metal pads includes at least five metal pads, and the second plurality of metal pads includes at least four metal pads.

5. The MR structure of claim 1 wherein the first plurality of metal pads includes a first metal pad corresponding to a first terminal of the MR element and a second metal pad corresponding to a second terminal of the MR element.

6. The MR structure of claim 5 wherein the two or more groups of parallel lines are connected to allow current to flow between the first and second terminals of the MR element.

7. The MR structure of claim 1 wherein the two or more groups of parallel lines each include parallel lines of equal width.

8. The MR structure of claim 7 wherein each of the parallel lines of the same width include at least two parallel lines with adjacent pairs of the two parallel lines separated by equal spacing.

9. The MR structure of claim 1 comprising a first plurality of unconnected lines provided on a first side of the one or more MR elements and a second plurality of unconnected lines provided on a second side of the one or more MR elements opposite from the first side, the first and second pluralities of unconnected lines being electrically isolated from the one or more MR elements.

10. The MR structure of claim 9 wherein the first and second pluralities of unconnected lines both comprise at least two unconnected lines.

11. The MR structure of claim 1 wherein the one or more MR elements includes at least two MR elements, wherein the serpentine layouts of the at least two MR elements are interleaved.

12. The MR structure of claim 11 wherein a first one of the at least two MR elements has a longer active area compared to a second one of the at least two MR elements.

13. The MR structure of claim 11 wherein the at least two MR elements are connected to form a half bridge.

14. The MR structure of claim 1 wherein the one or more MR elements includes four MR elements, wherein the serpentine layouts the four MR elements are interleaved.

15. The MR structure of claim 14 wherein the four MR elements are connected to form a full bridge.

16. A coil structure for exciting one or more magnetoresistance (MR) elements, the coil structure comprising:
a first plurality of parallel traces;
a second plurality of parallel traces;
a first plurality of return paths connecting first ends of the first plurality of parallel traces to first ends of the second plurality of parallel traces; and
a second plurality of return paths connecting seconds ends of the first plurality of parallel traces to second ends of the second plurality of parallel traces,
wherein the first and second pluralities of parallel traces extend in a first direction and the first and second pluralities of returns paths extend in a second direction perpendicular to the first direction.

17. The coil structure of claim 16 wherein the first and second pluralities of parallel traces are formed on one or more metal layers and the first and second pluralities of return paths are formed on at least two other metal layers.

18. A sensor comprising the coil structure of claim 16, wherein a first MR element is disposed over the first plurality of parallel traces, and a second MR element is disposed over the second plurality of parallel traces.

19. The sensor of claim 18 wherein the first MR element comprises a first plurality of parallel lines, and the second MR element comprises a second plurality of parallel lines.

20. The sensor of claim 19 wherein the first plurality of parallel lines are aligned with the first plurality of parallel traces, and the second plurality of parallel lines are aligned with the second plurality of parallel traces.

21. The sensor of claim 19 wherein ones of the first plurality of parallel traces are centered along respective ones of the first plurality of parallel lines, and ones of the second plurality of parallel traces are centered along respective ones of the second plurality of parallel lines.

22. The sensor of claim 19 wherein the first plurality of parallel lines are separated by a first plurality of spaces, the second plurality of parallel lines are separated by a second plurality of spaces, the first plurality of parallel traces are centered along respective ones of the first plurality of spaces, and the second plurality of parallel traces are centered along respective ones of the second plurality of spaces.

23. A method for reading a sensor matrix, the matrix having pixels arranged in rows and columns, each pixel corresponding to one or more magnetoresistance (MR) elements, and further having a plurality of excitation coils each arranged to excite one or more pixels, the method comprising:
at a first time, passing current through a first one of the excitation coils to excite a first plurality of the pixels and obtaining first magnetic field measurements from the corresponding MR elements; and
at a second time, passing current through a second one of the excitation coils to excite a second plurality of the pixels and obtaining second magnetic field measurements from the corresponding MR elements.

24. The method of claim 23 wherein exciting the first plurality of the pixels comprises exciting all pixels in a first row, and exciting the second plurality of the pixels comprises exciting all pixels in a second row.

25. The method of claim 23 wherein exciting the first plurality of the pixels comprises exciting adjacent pixels in a first row and exciting adjacent pixels in a second row.

26. The method of claim 25 wherein the first and second rows are offset by one, two, four, or six rows.
